(19) United States
(12) Patent Application Publication
(10) Pub. No.: US 2026/0327788 A1
(43) Pub. Date: Oct. 22, 2026

(54) METHOD OF FORMING METAL FILM AND APPARATUS FOR FORMING METAL FILM

(71) Applicant: Tokyo Electron Limited, Tokyo (JP)

(72) Inventors: Masayuki NASU, Nirasaki City (JP); Tatsuo HIRASAWA, Nirasaki City (JP)

(21) Appl. No.: 19/646,901

(22) Filed: Apr. 14, 2026

(30) Foreign Application Priority Data
Apr. 22, 2025 (JP) 2025-070848

(51) Int. Cl. C23C 16/04; C23C 16/14; C23C 16/455; C23C 16/505; C23C 16/52; H01J 37/32; H10W 20/00

(52) U.S. Cl. CPC C23C 16/045; C23C 16/14; C23C 16/45538; C23C 16/45544; C23C 16/45553; C23C 16/505; C23C 16/52; H01J 37/32449; H01J 37/32816; H10W 20/033; H01J 2237/3321

(57) ABSTRACT

A method of forming a metal film in a recess formed on a surface of a substrate, includes: supplying a metal raw material gas containing a metal to the substrate in which a surface of a semiconductor layer containing a dopant is exposed on a bottom surface of the recess; in parallel with the supplying the metal raw material gas, continuously supplying, to the substrate, a reaction gas for obtaining the metal film by reacting with the metal raw material gas; and continuously applying radio frequency power to a space through which the metal raw material gas and the reaction gas flow, to plasma-activate the metal raw material gas and the reaction gas, wherein the supplying the metal raw material gas includes: continuously supplying the metal raw material gas; and alternately repeating supply and stop of the metal raw material gas after the continuously supplying the metal raw material gas.

### CROSS-REFERENCE TO RELATED APPLICATION

This application is based upon and claims the benefit of priority from Japanese Patent Application No. 2025-070848, filed on Apr. 22, 2025, the entire contents of which are incorporated herein by reference.

### TECHNICAL FIELD

The present disclosure relates to a method of forming a metal film and an apparatus for forming a metal film.

### BACKGROUND

In a manufacturing process of a semiconductor device, a processing of forming a metal film is performed on a semiconductor wafer serving as a substrate (hereinafter also referred to as a “wafer”).

For example, Patent Document 1 describes a technique in which, in forming a titanium film in a recess formed on a surface of a substrate, a titanium raw material gas is supplied to the substrate and radio frequency power is applied to plasma-activate the titanium raw material gas. According to the description of Patent Document 1, a titanium film having a uniform film thickness is formed by alternately repeating turning on and off the radio frequency power to be applied and alternately stopping application of the radio frequency power a plurality of times.

Further, Patent Document 2 describes a technique in which, during formation of a Ti film, a first step of generating first plasma while introducing a Ti compound gas and a reducing gas and a second step of generating second plasma while stopping the Ti compound gas and introducing the reducing gas are alternately repeated a plurality of times. It is described that, by repeating these steps, a reducing action for reducing a Ti compound is enhanced and a concentration of residues in the film is reduced, thereby obtaining a good film quality with a low resistivity.

On the other hand, Patent Documents 1 and 2 do not disclose a film forming method that takes into consideration influence of a metal film formation processing on an underlayer side of a substrate as a processing target.

### PRIOR ART DOCUMENTS

### Patent Documents

Patent Document 1: Japanese Patent Laid Open Publication No. 2023-055111
Patent Document 2: Japanese Patent Laid Open Publication No. 2004-232080

### SUMMARY

According to one embodiment of the present disclosure, there is provided a method of forming a metal film in a recess formed on a surface of a substrate, including: supplying a metal raw material gas containing a metal to the substrate in which a surface of a semiconductor layer containing a dopant is exposed on a bottom surface of the recess; in parallel with the supplying the metal raw material gas, continuously supplying, to the substrate, a reaction gas for obtaining the metal film by reacting with the metal raw material gas; and continuously applying radio frequency power to a space through which the metal raw material gas and the reaction gas flow, to plasma-activate the metal raw material gas and the reaction gas, wherein the supplying the metal raw material gas includes: continuously supplying the metal raw material gas; and alternately repeating supply and stop of the metal raw material gas, after performing the continuously supplying the metal raw material gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an enlarged vertical cross-sectional view of vicinity of a surface of a wafer on which a Ti film is formed.

FIG. 2 is a time chart relating to gas supply during formation of a Ti film according to a conventional embodiment.

FIG. 3 is a photograph of a surface of a wafer on which the Ti film has been formed according to the conventional embodiment.

FIGS. 4A and 4B are explanatory diagrams illustrating characteristics of the Ti film formed according to the conventional embodiment.

FIG. 5 is a time chart relating to gas supply during formation of a Ti film according to an improved embodiment.

FIGS. 6A and 6B are explanatory diagrams illustrating characteristics of the Ti film formed according to the improved embodiment.

FIG. 7 is an explanatory diagram illustrating resistance characteristics of Ti films formed by different methods.

FIG. 8 is a time chart relating to gas supply during formation of a Ti film according to a first verification embodiment.

FIG. 9 is a time chart relating to gas supply during formation of a Ti film according to a second verification embodiment.

FIG. 10A is a schematic diagram illustrating a region near a surface of a silicon layer exposed on a bottom surface of a recess.

FIG. 10B is an explanatory diagram illustrating an action of hydrogen plasma on a dopant contained in the silicon layer.

FIG. 11A is an explanatory diagram illustrating a state in which a boron concentration-reduced region is formed in the silicon layer.

FIG. 11B is an explanatory diagram illustrating a state in which a boron depletion region is formed in the silicon layer.

FIG. 12 is an explanatory diagram illustrating concentration distributions of boron in the silicon layer.

FIG. 13 is a time chart relating to gas supply during formation of a Ti film according to the present embodiment.

FIG. 14 is a vertical cross-sectional side view illustrating a configuration example of a film forming apparatus for forming a Ti film.

FIG. 15 is an explanatory diagram illustrating influence of pressure during film formation on selectivity of Ti film formation on a bottom surface/sidewall surface of a recess.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Formation of Ti Film>

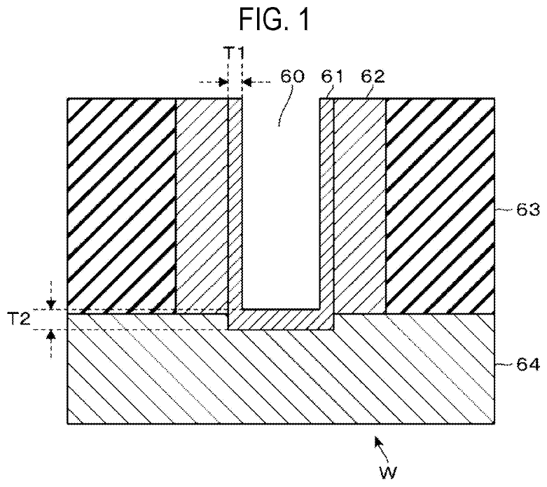

First, a configuration example of a substrate to which a method for forming a metal film according to an embodiment is applied is described with reference to FIG. 1. In the following example, a case in which a titanium (Ti) film 61 is formed as the metal film is described.

FIG. 1 schematically illustrates a configuration of a region near a surface of a wafer W, which is a substrate serving as a target for forming the Ti film 61. A silicon layer 64, which is a semiconductor layer containing a dopant for forming a carrier, is formed on the surface of the wafer W, and a surface of the silicon layer 64 is covered with a SiO₂ layer 63 serving as an insulating film. A recess 60 in which formation of the Ti film 61 is performed is provided in the SiO₂ layer 63.

The recess 60 is configured, for example, as a contact hole having an opening diameter of 40 nm within a range of 30 to 50 nm and a depth of 120 nm within a range of 90 to 200 nm. A TiN film 62, which is a barrier film for suppressing diffusion of a metal (for example, Ti) into the SiO₂ layer 63, may be formed on a sidewall surface of the recess 60. The surface of the silicon layer 64 on an underlayer side is exposed on a bottom surface of the recess 60.

Conventionally, the Ti film 61 has been formed, for example, by a plasma chemical vapor deposition (CVD) method. In the plasma CVD method, a Ti raw material gas (metal raw material gas) and a reaction gas to be reacted with the Ti raw material gas are supplied, and radio frequency power is applied to a space through which these gases flow. By application of the radio frequency power, the respective gases are plasma-activated to generate active species, and by reactions of these active species, Ti is deposited in the recess 60 to form the Ti film 61.

An example of the Ti raw material gas may include a titanium tetrachloride (TiCl₄) gas containing chlorine atoms, and an example of the reaction gas may include a hydrogen (H₂) gas. Further, an argon (Ar) gas may be added to these gases for the purpose of assisting plasma generation.

### Conventional Embodiment and Problems

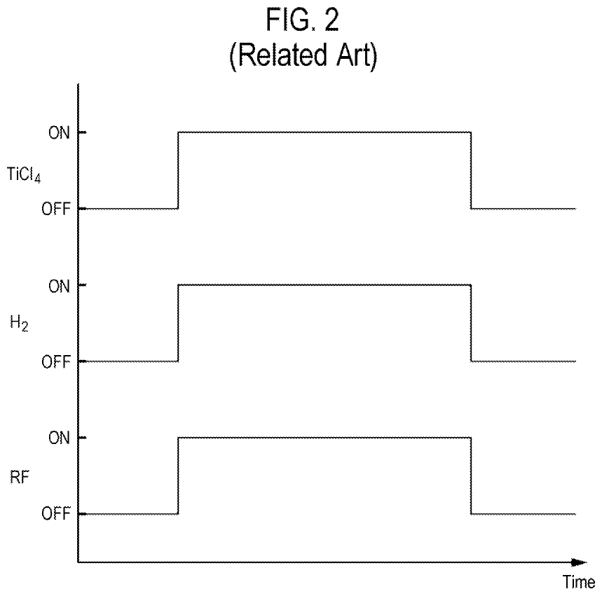

FIG. 2 illustrates a time chart relating to gas supply during formation of the Ti film 61 according to a conventional embodiment. In the time charts of FIGS. 2, 5, 8, 9, and 13 described below, the horizontal axis represents time. Further, the vertical axis represents a state in which a TiCl₄ gas and a H₂ gas (including an Ar gas; the same applies hereinafter) are supplied, or radio frequency power (RF) is applied when illustrated as “ON,” and a state in which supply of these gases and application of RF are stopped when illustrated as “OFF.”

According to the time chart of FIG. 2, in the conventional embodiment, supply of the TiCl₄ gas and H₂ gas to the wafer W and application of RF are simultaneously started. Then, after a predetermined time (for example, 360 seconds) has passed, the supply of the TiCl₄ gas and H₂ gas and the application of RF are simultaneously stopped.

Here, in order to further suppress influence on the wafer W during formation of the Ti film 61, the disclosers of the present disclosure have studied lowering a processing temperature during formation of the Ti film 61, which has been performed, for example, at 450 degrees C. As a target processing temperature, for example, 400 degrees C. within a range of 390 to 410 degrees C. may be exemplified.

However, it has been found that the method for forming the Ti film 61 according to the conventional embodiment as illustrated in FIG. 2 has the following two problems when lowering the processing temperature.

The first problem is that the Ti film 61 on the bottom surface of the recess 60 becomes thin. For example, in the recess 60 forming a contact hole, film formation is required such that a film thickness T2 of the Ti film 61 on the bottom surface is increased, while a film thickness T1 of the Ti film 61 on the sidewall surface is prevented from becoming excessively thick.

However, as shown in experimental results of a comparative example described later, it has been found that when the supply of the TiCl₄ gas and H₂ gas and the application of RF are continuously performed based on the time chart illustrated in FIG. 2, the film thickness T2 on the bottom surface becomes significantly thin as the processing temperature is lowered.

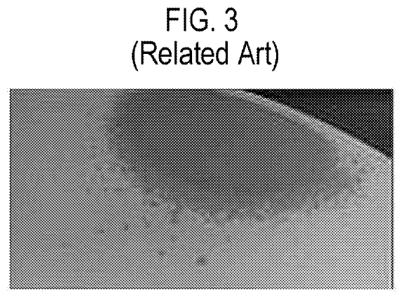

The second problem is deterioration of film quality. FIG. 3 is an enlarged photograph of the surface of the wafer W after the formation of the Ti film 61 at the processing temperature of 400 degrees C. and subsequent exposure to the atmosphere. It can be confirmed from FIG. 3 that a darkened region is formed on the surface of the wafer W. When this region was visually observed on the actual wafer W, surface roughening and film swelling were confirmed.

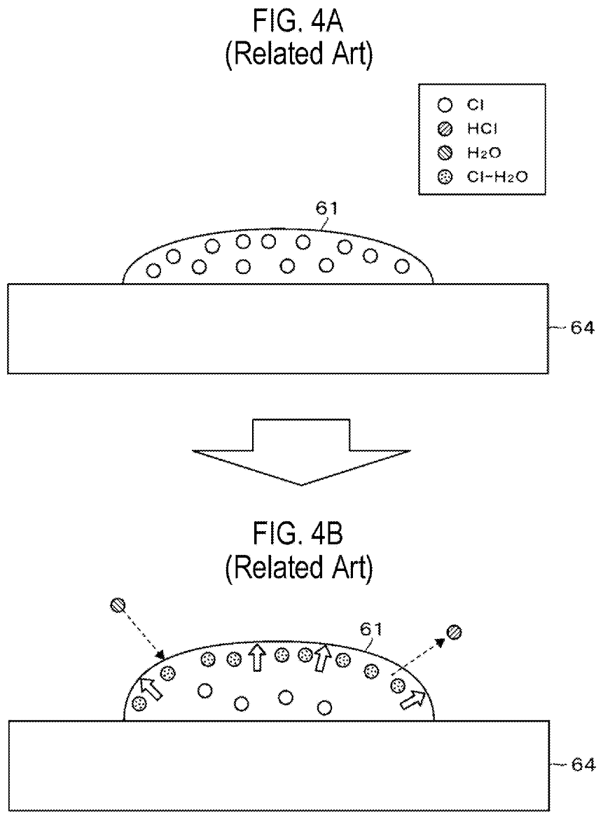

A mechanism presumed to cause such deterioration of the film quality of the Ti film 61 is described with reference to FIGS. 4A and 4B. FIG. 4A schematically illustrates a state during the formation of the Ti film 61. The active species of TiCl₄ obtained by plasma-activation through the application of RF react with the active species of H₂ to deposit Ti, thereby forming the Ti film 61. At this time, if the processing temperature is lowered to 400 degrees C., reduction of TiCl₄ by H₂ does not proceed sufficiently, and an amount of residual chlorine (Cl) in the Ti film 61 increases.

FIG. 4B schematically illustrates a state of the Ti film 61 after the formation of the Ti film 61 has been completed and the wafer W has been taken out from an apparatus in which the processing was performed. Cl remaining in the Ti film 61 readily bonds with moisture in the atmosphere. As a result, the Ti film 61 expands, resulting in non-uniformity of an in-plane film thickness of the wafer W and deterioration of the film quality. Further, the Ti film 61 that has reacted with moisture in the atmosphere exhibited deliquescence in which a part of the film became liquefied. Further, compounds formed by bonding between Cl and H₂O, as well as hydrogen chloride (HCl) generated by reactions of such compounds, are themselves corrosive and become factors that cause corrosion-induced roughening on a surface of the Ti film 61. From this viewpoint, it may be said that a TiCl₄ gas contains atoms (Cl) that react with moisture in the atmosphere to generate corrosive substances when remaining in the Ti film 61.

### Improved Embodiment and New Problem

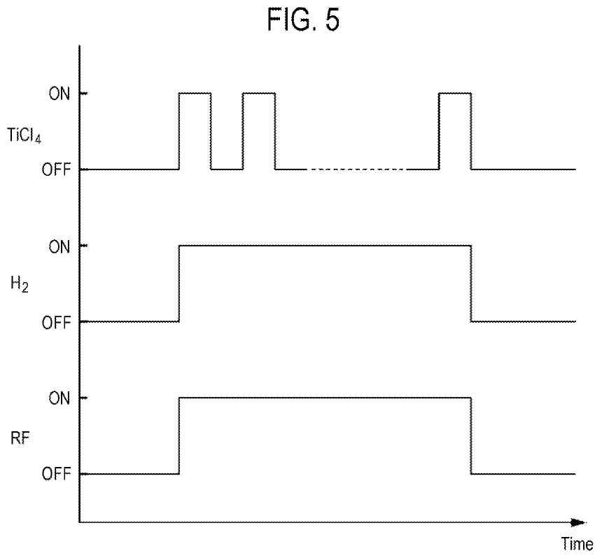

In solving the above-described two problems, the disclosers considered that it is necessary to secure a time during which the active species of H₂ sufficiently react with the active species of TiCl₄ and a time during which Cl remaining in the Ti film 61 is sufficiently desorbed. From this viewpoint, instead of the method described with reference to FIG. 2 in which the supply of the TiCl₄ gas and H₂ gas and the application of RF are continuously performed, an improved embodiment illustrated in FIG. 5 was studied. In the improved embodiment, while the supply of the H₂ gas and the application of RF are continuously performed, supply and stop of the TiCl₄ gas are alternately repeated.

As an example of setting supply time/stop time when the supply and stop of the TiCl₄ gas are alternately repeated, the supply time for one cycle may be 6 seconds within a range of 1 to 10 seconds, and the stop time may be 4 times the supply time within a range of 1 to 5 times the supply time (when the supply time is 6 seconds, the stop time is 24 seconds). Then, a supply/stop cycle is repeated such that a cumulative value of the supply time of the TiCl₄ gas reaches a preset target value (240 seconds in Examples described later).

By providing a period in which the supply of the TiCl₄ gas is stopped in this manner, the H₂ gas sufficiently reaches the bottom surface of the recess 60, and a reaction time between the active species of TiCl₄ and the active species of H₂ is secured. As a result, as shown in Examples described later, it can be confirmed that selectivity of formation of the Ti film 61 on the bottom surface of the recess 60 is enhanced, as compared with the case based on the time chart of FIG. 2.

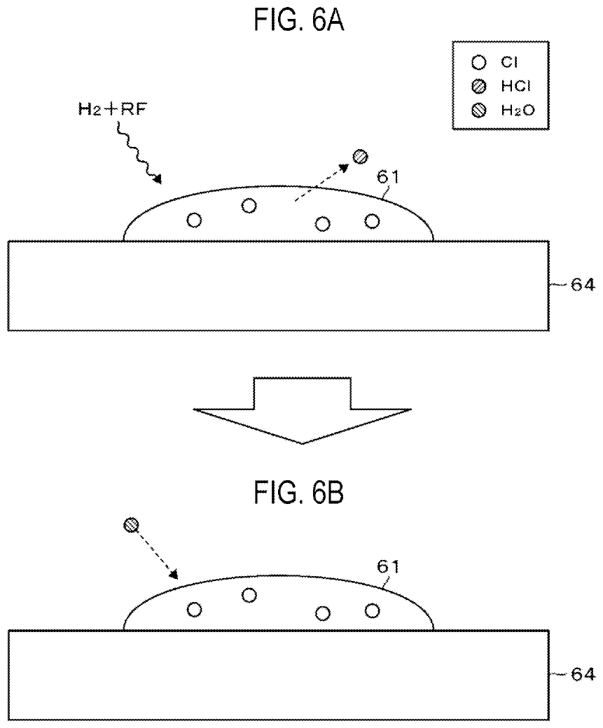

Further, by securing a sufficient reaction time between the active species of TiCl₄ and the active species of H₂, Cl atoms that generate HCl, which is a corrosive substance, are released when the active species of H₂ formed by plasma (hereinafter also simply referred to as “plasma-activated H₂ gas”) come into contact with the Ti film 61, as schematically illustrated in FIG. 6A. As a result, the amount of Cl remaining in the Ti film 61 may be reduced, thereby minimizing an amount of H₂O introduced into the Ti film 61. By minimizing the amount of H₂O introduced, expansion of the Ti film 61 is suppressed and the in-plane film thickness of the wafer W is maintained uniform, thereby suppressing a deliquescence phenomenon in which a portion of the Ti film 61 is liquefied and an occurrence of surface roughening of the Ti film 61 accompanied by the release of HCl (FIG. 6B).

As described above, the method for forming the Ti film 61 based on the time chart illustrated in FIG. 5 may increase the selectivity of formation of the Ti film 61 on the bottom surface of the recess 60 and improve the film quality. On the other hand, it was found that a new problem described later arises.

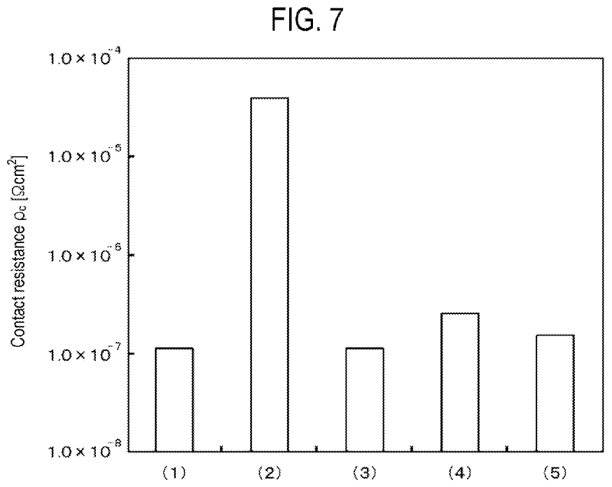

FIG. 7 is a graph comparing resistance characteristics of wafers W on which the Ti film 61 was formed when the supply method of TiCl₄ was variously changed. The resistance characteristics of the wafer W were obtained by measuring contact resistance pc of the wafer W along a film thickness direction of the Ti film 61 by the Kelvin method and comparing contact resistance values at a position corresponding to 50% of the film thickness. As described later, during formation of the Ti film 61, a heating temperature (processing temperature) of the wafer W was unified to 400 degrees C., and a processing pressure was unified to 133.3 Pa (1 Torr).

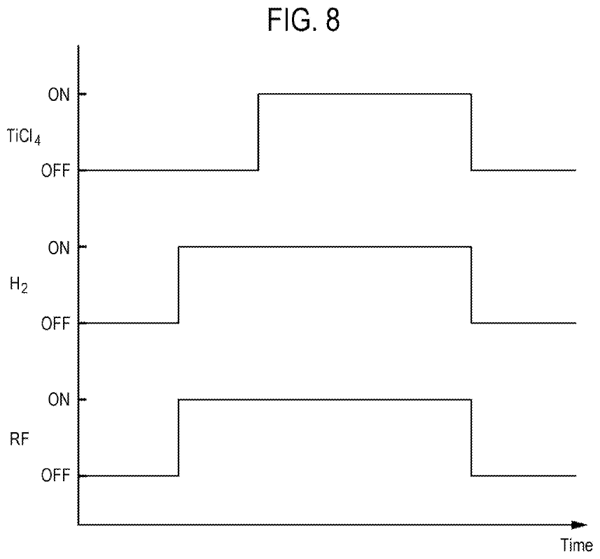

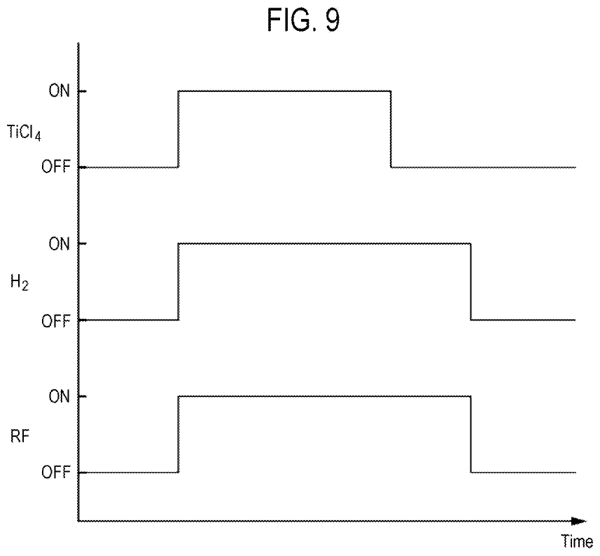

In the graph of FIG. 7, the contact resistance value of the wafer W on which the Ti film 61 was formed according to the conventional embodiment as illustrated in FIG. 2 is indicated as No. (1). Further, the contact resistance value of the wafer W on which the Ti film 61 was formed according to the improved embodiment in which the supply and stop of the TiCl₄ gas were alternately repeated as illustrated in FIG. 5 is indicated as No. (4). Next, No. (2) indicates the contact resistance value of the wafer W when, as illustrated in FIG. 8 (first verification embodiment), only the supply of the H₂ gas and the application of RF were performed for 750 seconds and thereafter, the Ti film 61 was formed according to the conventional embodiment as illustrated in FIG. 2. Further, No. (5) indicates the contact resistance value of the wafer W when, as illustrated in FIG. 9 (second verification embodiment), after the Ti film 61 was formed according to the conventional embodiment as illustrated in FIG. 2, only the supply of the H₂ gas and the application of RF were performed for 750 seconds. In addition, the method for forming the Ti film 61 corresponding to No. (3) is described later.

Herein, when comparing No. (1) corresponding to the conventional embodiment with No. (4) corresponding to the improved embodiment, the contact resistance value was increased in the improved embodiment in which the Ti film 61 was formed by repeating the supply and stop of the TiCl₄ gas. This result showed the same tendency not only at the position corresponding to 50% of the film thickness of the Ti film 61 but also throughout the entire Ti film 61.

Further, regarding other film forming methods, in No. (2) corresponding to the first verification embodiment in which only the supply of the H₂ gas and the application of RF were performed before the formation of the Ti film 61, the contact resistance value of the wafer W deteriorated significantly. On the other hand, in No. (5) corresponding to the second verification embodiment in which only the supply of the H₂ gas and the application of RF were performed after the formation of the Ti film 61, the contact resistance value of the wafer W was approximately the same level as that of the conventional embodiment.

When comparing the resistance characteristics of the wafers W having the Ti film 61 formed by these different methods, it can be confirmed that the contact resistance value of No. (2) corresponding to the first verification embodiment in which the Ti film 61 was formed based on the time chart of FIG. 8 is significantly high. In the first verification embodiment, the supply of the H₂ gas and the application of RF are performed before the formation of the Ti film 61, and as such the wafer W in a state not covered with the Ti film 61 is directly exposed to the plasma-activated H₂ gas.

On the other hand, the contact resistance value of No. (5) corresponding to the second verification embodiment in which the Ti film 61 was formed based on the time chart of FIG. 9 does not show a significant increase in the contact resistance value, as compared with No. (1) in which the Ti film 61 was formed according to the conventional embodiment as illustrated in FIG. 2. Thus, based on the fact that a large difference in the contact resistance value occurs depending on a difference in timing of performing only the supply of the H₂ gas and the application of RF (No. (2): before the formation of the Ti film 61, No. (5): after the formation of the Ti film 61), a cause of the deterioration of resistance characteristics was estimated as follows.

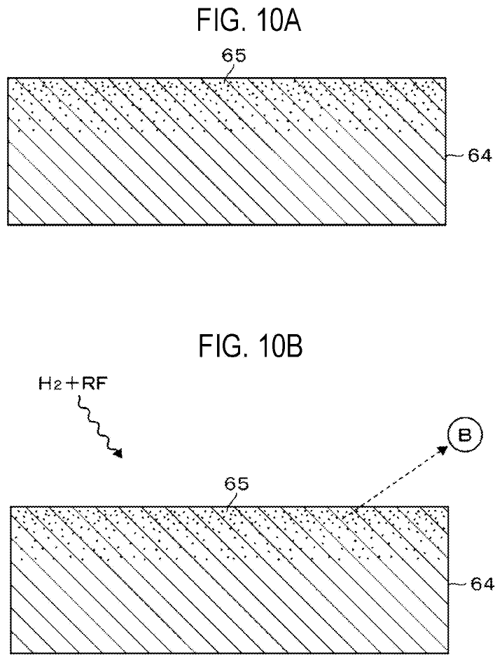

Herein, the silicon layer 64 of the wafer W contains, as dopants, Group III elements (for example, boron (B), indium (In), and gallium (Ga)) as impurities in the case of a p-type semiconductor. Further, in the case of an n-type semiconductor, the silicon layer 64 contains, as dopants, Group V elements (for example, phosphorus (P), arsenic (As), and antimony (Sb)) as impurities. In these cases, the silicon layer 64 may have a configuration in which dopants other than Ga are contained in a SiGe region containing about 30 to 50 at % Ga in silicon, for example. Hereinafter, as illustrated in FIG. 10A, an example is described in which a boron-containing region 65 that contains B as a dopant is formed in a region near the surface of the wafer W. In the example illustrated in FIG. 10A, the boron-containing region 65 is exposed on the bottom surface of the recess 60 before the Ti film 61 is formed.

A case is conceivable in which RF is applied and the plasma-activated H₂ gas is supplied to the wafer W in a state in which the boron-containing region 65 is exposed before being covered with the Ti film 61, as illustrated in FIG. 10B. For convenience of illustration, in FIG. 10B, a state in which the plasma-activated H₂ gas is supplied is described as “H₂+RF.”

While the plasma-activated H₂ gas has high reactivity, the plasma-activated TiCl₄ gas is not supplied to the wafer W, and therefore it is not possible to carry out a reaction for forming the Ti film 61. Therefore, the plasma-activated H₂ gas acts directly on the boron-containing region 65, and a part thereof causes a reaction that removes boron from the boron-containing region 65.

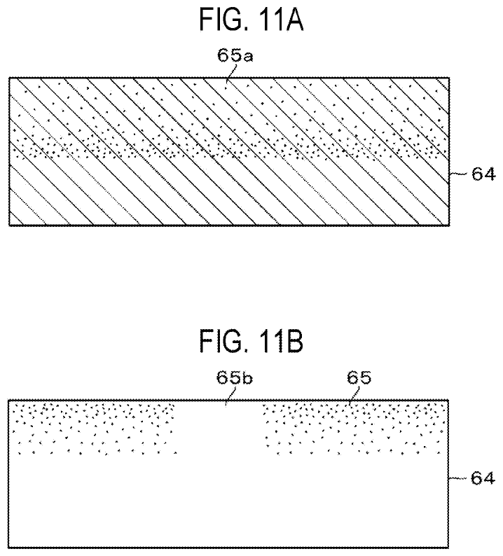

As a result, a concentration-reduced region 65a having a low boron concentration may be formed on the surface of the wafer Was illustrated in FIG. 11A, or a depletion region 65b containing almost no boron may be formed in a portion of an exposed region on the surface of the wafer Was illustrated in FIG. 11B. Then, presence of the concentration-reduced region 65a or the depletion region 65b becomes a factor that increases the contact resistance value of the wafer W on which the Ti film 61 is formed.

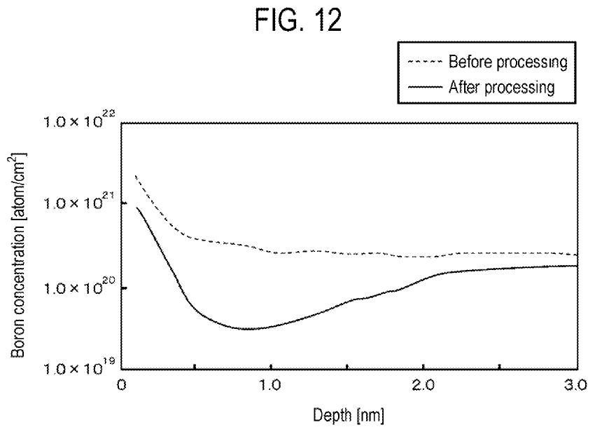

FIG. 12 illustrates results of measuring concentration distributions of B along a depth direction of the wafer W before and after performing the processing using the plasma-activated H₂ gas with respect to the boron-containing region 65 that contains B as a dopant, in order to verify the presumed mechanism described above. Concentration analysis of B was performed by a secondary ion mass spectrometry (SIMS) method. The boron-containing region 65 was formed in a SiGe region, and before performing the processing using the plasma-activated H₂ gas, a chemical oxide removal (COR) processing was performed on the wafer W by supplying a hydrofluoric acid (HF) gas and ammonia (NH₃) gas to remove a silicon oxide film.

In FIG. 12, the horizontal axis represents a depth position from the surface of the wafer W, and the vertical axis represents a logarithmic value of a boron concentration. The dashed line illustrated in FIG. 12 represents the concentration distribution of boron on the wafer W before any processing, and the solid line represents the concentration distribution of boron after performing the processing using the plasma-activated H₂ gas. In addition, before and after performing the COR processing, a substantially same concentration variation as the B concentration distribution before the processing was observed, except that the B concentration was slightly reduced in a region near the surface of the wafer W (within a range of approximately 0.1 to 0.3 nm), and therefore illustration thereof is omitted.

According to the results illustrated in FIG. 12, a tendency is exhibited in which the boron concentration after the processing using the plasma-activated H₂ gas is lower than that before the processing over an entire measured depth range. In particular, it can be confirmed that there is a region in which the boron concentration after the processing is significantly reduced within a depth range of approximately 0.5 to 2.0 nm. This suggests that the concentration-reduced region 65a having a low boron concentration as illustrated in FIG. 11A is formed near the surface of the wafer W.

As discussed above, when the plasma-activated H₂ gas is supplied to the wafer W in a state not covered with the Ti film 61, dopants may be released and the resistance characteristics may deteriorate. It is considered that a similar tendency is exhibited also in a case where the Ti film 61 is formed based on the time chart of FIG. 5. That is, by repeating the supply and stop of the TiCl₄ gas within a short time, the plasma-activated H₂ gas is supplied to the wafer W on which the formation of the Ti film 61 is insufficient. As a result, although a remarkable increase in the contact resistance as in No. (2) in which the plasma-activated H₂ gas is supplied to the wafer W on which the Ti film 61 is not formed at all is not observed, it is considered that the resistance characteristics corresponding to No. (4) in which the contact resistance value is higher than that of No. (1) of the conventional embodiment are obtained.

According to the presumed mechanism described above, as illustrated in FIG. 10B, when the plasma-activated H₂ gas is supplied to the boron-containing region 65 exposed on the surface of the wafer W, dopants are released and the resistance characteristics deteriorate. Therefore, it is considered that it is possible to suppress deterioration of the resistance characteristics caused by the release of dopants if a surface of the boron-containing region 65 is covered with the Ti film 61. However, in forming the Ti film 61 based on the time chart of FIG. 5 suitable for low-temperature film formation, since the supply time of the TiCl₄ gas in each cycle is short, the surface of the boron-containing region 65 is brought into contact with the plasma-activated H₂ gas before being covered with the Ti film 61.

### Method for Forming Ti Film According to Present Embodiment

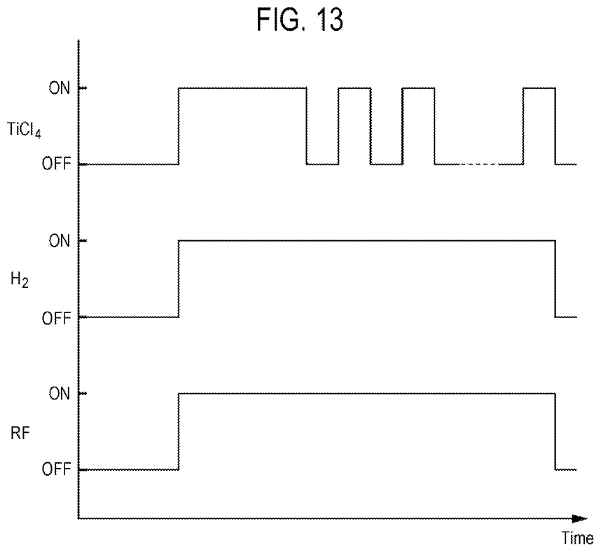

In view of such problems, the disclosers of the present disclosure devised a method in which a TiCl₄ gas supply step (a step of supplying a metal raw material gas) is divided into two steps, as illustrated in FIG. 13. In this method, in a first step performed first, the TiCl₄ gas is continuously supplied so that the surface of the boron-containing region 65 is covered with the Ti film 61. In a second step performed subsequently, by alternately repeating supply and stop of the TiCl₄ gas, the Ti film 61 having high selectivity for the bottom surface of the recess 60 and having a good film quality is formed.

On the other hand, the supply of H₂ gas and application of RF are performed continuously, as in the conventional embodiment, in parallel with execution of the first step and the second step (a step of continuously supplying a reaction gas and a step of continuously applying radio frequency power).

In the first step, the supply of the TiCl₄ gas is continuously performed, for example, for 30 to 120 seconds so that the Ti film 61 covering the boron-containing region 65 is formed on the wafer W. If the supply time of the TiCl₄ gas in the first step is less than 30 seconds, there is a risk that only the plasma-activated H₂ gas is supplied for a prolonged time in a state in which the formation of the Ti film 61 is insufficient. Further, if the supply time of the TiCl₄ gas in the first step exceeds 120 seconds, a period in which the Ti film 61 is formed by the same method as in the conventional embodiment becomes long, and it becomes difficult to obtain the effects of improving the selectivity with respect to the bottom surface of the recess 60 and forming the Ti film 61 having a good film quality.

Further, in the second step, the Ti film 61 is formed in substantially the same manner as in the time chart described with reference to FIG. 5. That is, an example may be given in which a single supply time of the TiCl₄ gas is 6 seconds within a range of 1 to 10 seconds and the stop time is 4 times the supply time within a range of 1 to 5 times the supply time (when the supply time is 6 seconds, the stop time is 24 seconds). Then, the supply/stop cycle is repeated such that a cumulative value of the supply time of the TiCl₄ gas over both the first step and the second step becomes a preset target value (240 seconds in Examples described later).

In the formation of the Ti film 61 including the first step and the second step, the processing temperature (heating temperature of the wafer W) is set, for example, to 410 degrees C. within a range of 390 to 410 degrees C. Further, as illustrated in Examples described later, in the formation of the Ti film 61, a tendency is observed in which the selectivity of the formation of the Ti film 61 with respect to the bottom surface of the recess 60 becomes higher when the processing pressure is lowered. From this viewpoint, a case may be exemplified in which the formation of the Ti film 61 based on the time chart illustrated in FIG. 13 is performed under a pressure condition within a range of 106.7 to 200 Pa (0.8 to 1.5 Torr).

As a result of forming the Ti film 61 based on the time chart illustrated in FIG. 13 according to the above-described method for forming the Ti film 61, the contact resistance value at a position corresponding to 50% of the film thickness became the value indicated as No. (3) in FIG. 7. This can be evaluated as resistance characteristics substantially similar to those in the formation of the Ti film 61 based on the time chart of the conventional embodiment.

Here, the formation conditions of the Ti film 61 corresponding to No. (3) are as follows: processing temperature: 400 degrees C., processing pressure: 133.3 Pa (1 Torr), execution time of the first step: 80 seconds, supply time of the TiCl₄ gas in the second step: 6 seconds, stop time of the TiCl₄ gas in the second step: 24 seconds (4 times the supply time), and the number of repetitions of the supply/stop of the TiCl₄ gas: 50 times. Accordingly, the cumulative value of the supply time of the TiCl₄ gas over a first period and a second period is 240 seconds.

### <Film Forming Apparatus>

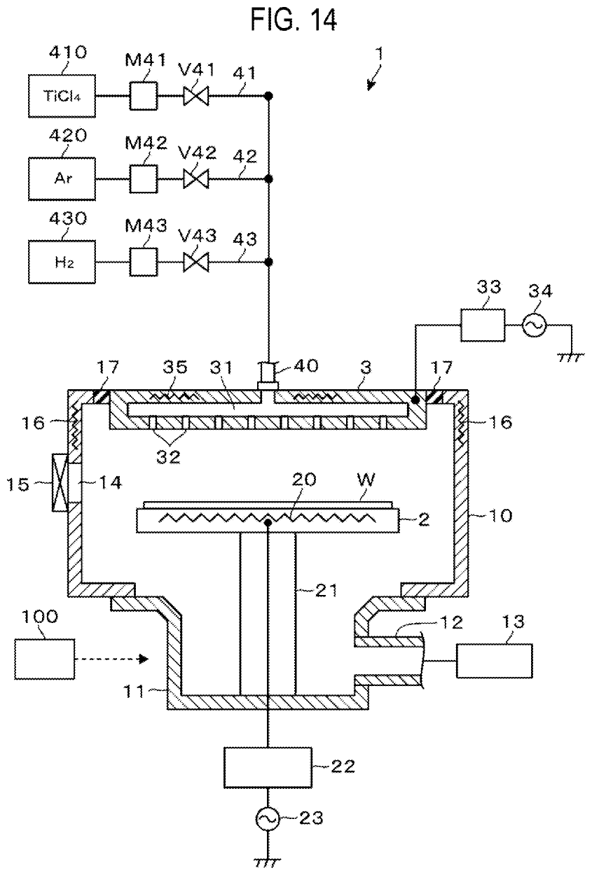

A configuration example of an apparatus (film forming apparatus 1) for carrying out the above-described method for forming the Ti film 61 according to the present embodiment is described. FIG. 14 is a vertical cross-sectional side view of the film forming apparatus 1 according to the present embodiment. The film forming apparatus 1 is configured as an apparatus which supplies the TiCl₄ gas and the H₂ gas to the surface of the wafer W and forms the Ti film 61 by a plasma CVD method based on the time chart described with reference to FIG. 13.

The film forming apparatus 1 includes a substantially cylindrical metallic processing container 10 that is grounded and has corrosion resistance to chlorine. The wafer W is processed in a space within the processing container 10. For example, a cylindrical exhaust chamber 11 is formed at a central portion of a bottom surface of the processing container 10 to protrude downward, and an exhaust path 12 is connected to a side surface of the exhaust chamber 11. A vacuum exhauster 13 including a pressure adjustment valve, which is formed of, for example, a butterfly valve, is connected to the exhaust path 12, and is configured to be capable of depressurizing an interior of the processing container 10 to a preset vacuum pressure (for example, the aforementioned 106.7 to 200 Pa (0.8 to 1.5 Torr)). The exhaust path 12 and the vacuum exhauster 13 correspond to a pressure adjuster of the present embodiment.

A loading/unloading port 14 for loading and unloading the wafer W between the processing container 10 and a vacuum transfer chamber (not illustrated) is formed on a side surface of the processing container 10. The loading/unloading port 14 is configured to be capable of being opened or closed by a gate valve 15. Further, a heater 16 is embedded in a wall constituting the processing container 10 to adjust a temperature of the processing container 10.

Further, a stage 2 for holding the wafer W substantially horizontally is provided in the processing container 10. The stage 2 is supported by a support 21 extending from a bottom of the exhaust chamber 11. A heater 20 serving as a heating part is embedded in the stage 2 and is capable of heating the wafer W to a set temperature. In the present embodiment, the heating temperature of the wafer W is set, for example, to 400 degrees C. within a range of 390 to 410 degrees C.

Further, a radio frequency power source 23 is connected to the stage 2 via a matcher 22 to supply radio frequency power for ion attraction. Further, lifting pins (not illustrated) for holding and vertically moving the wafer W on the stage 2 are provided in the stage 2. The wafer W may be delivered between the stage 2 and an external transferrer (not illustrated) by the vertical movements of the lifting pins.

Further, a shower head 3 having a flat disk shape is provided on a ceiling surface of the processing container 10 to supply a substrate processing gas toward the wafer W. The shower head 3 is attached to the processing container 10 via an insulating member 17.

An interior of the shower head 3 forms a diffusion space 31 for diffusing a gas. Further, a large number of discharge holes 32 are provided on a bottom surface of the shower head 3 in a distributed manner to discharge the gas toward the wafer W. Furthermore, a heater 35 is embedded in an upper surface side of the shower head 3.

A radio frequency power source 34 is connected to the shower head 3 via a matcher 33 to supply radio frequency power for plasma generation. That is, the film forming apparatus 1 of the present disclosure constitutes a parallel-plate-type plasma processing apparatus by the shower head 3 serving as an upper electrode and the stage 2 serving as a lower electrode. The wafer W is placed in a space between the shower head 3 and the stage 2, and by supplying gases such as the TiCl₄ gas and the H₂ gas and also applying radio frequency power, these gases are ionized to form plasma.

The radio frequency power source 34 may be configured to supply radio frequency power at any frequency of 450 KHz, 13.56 MHz, 915 MHz, or 2.45 GHz. Further, radio frequency power greater than 0 W and not more than 2,000 W, for example, 300 W, is supplied from the radio frequency power source 34. The radio frequency power source 34 corresponds to a radio frequency power supply of the present embodiment.

Further, a downstream side end of a gas supply path 40 is connected to the diffusion space 31 of the shower head 3. A TiCl₄ gas supply pipe 41 serving as a supply flow path for the TiCl₄ gas, which is a titanium raw material gas, and a H₂ gas supply pipe 43 serving as a supply flow path for the H₂ gas, which is a reaction gas, are joined together on an upstream side of the gas supply path 40. Furthermore, an Ar gas supply pipe 42 serving as a supply flow path for the Ar gas added for plasma generation is connected to the gas supply path 40.

A TiCl₄ gas supply source 410 is connected to an end of an upstream side of the TiCl₄ gas supply pipe 41, and a flow rate adjuster M41 and a valve V41 are installed in this order from the upstream side (raw material gas supply). Further, an Ar gas source 420 is connected to an end of an upstream side of the Ar gas supply pipe 42, and a flow rate adjuster M42 and a valve V42 are installed in this order from the upstream side. Furthermore, a H₂ gas supply source 430 is connected to an end of an upstream side of the H₂ gas supply pipe 43, and a flow rate adjuster M43 and a valve V43 are installed in this order from the upstream side (reaction gas supply).

These TiCl₄ gas, H₂ gas, and Ar gas are introduced into the diffusion space 31 of the shower head 3 through the gas supply path 40 in a mixed state, and are supplied into the processing container 10 through the discharge holes 32.

The film forming apparatus 1 having the above-described configuration includes a controller 100 as illustrated in FIG. 14. The controller 100 is configured by a computer including a storage storing a program, a memory, and a CPU. The program is configured with instructions (steps) for executing respective steps for forming the Ti film 61 by outputting control signals from the controller 100 to respective parts of the film forming apparatus 1 and controlling supply and shutoff of each gas as well as supply of the radio frequency power. The program is stored in the storage of the computer, such as a flexible disk, compact disk, hard disk, magneto-optical (MO) disk, non-volatile memory, or the like, and is read from the storage and installed in the controller 100.

### <Operation of Film Forming Apparatus>

An operation of the film forming apparatus 1 having the above-described configuration is described.

First, the gate valve 15 is opened, and the wafer W is loaded through the loading/unloading port 14 by the transferrer provided in the vacuum transfer chamber (not illustrated). The loaded wafer W is delivered from the transferrer to the stage 2 via the lifting pins (not illustrated) and is placed on an upper surface of the stage 2. Next, after the transferrer is retracted from the processing container 10 and the gate valve 15 is closed, vacuum-exhausting of the processing container 10 is performed by the vacuum exhauster 13 to adjust the interior of the processing container 10 to a preset pressure. In addition, the wafer W is heated to the above-described 400 degrees C. by the heater 20.

Thereafter, based on the time chart illustrated in FIG. 13, the continuous supply of the H₂ gas, the application of the RF, and the continuous supply of the TiCl₄ gas are performed to execute the first step. After the first step has been performed for a preset time in this manner, the operation is switched to execution of the second step in which the supply and the stop of the TiCl₄ gas are alternately repeated. At this time, the continuous supply of the H₂ gas and the application of the RF are continued. In addition, in the present example, the Ar gas is also continuously supplied during a period in which the RF is applied, and the supply of the Ar gas is stopped when the application of the RF is stopped.

In this way, the Ti film 61 having a preset film thickness is formed by performing the first step and the second step according to the time chart illustrated in FIG. 13. Next, the supply of the TiCl₄ gas and H₂ gas and the application of the RF are terminated, and heating of the wafer W is also stopped. Thereafter, the wafer W is unloaded from the processing container 10 in a procedure reverse to that during loading, and the apparatus awaits loading of a next wafer W.

### <Effects>

The following effects are obtained according to the embodiment described above. The step of supplying the TiCl₄ gas, which is a Ti raw material gas, is divided into two steps, and in the first step, the TiCl₄ gas is continuously supplied. As a result, in addition to preventing the boron-containing region 65 from being exposed solely to the plasma-activated H₂ gas and releasing boron (B) serving as a dopant, it is possible to cover the surface of the boron-containing region 65 with the Ti film 61. Subsequently, by performing the second step in which the supply and stop of the TiCl₄ gas are alternately repeated, the Ti film 61 having high selectivity with respect to the bottom surface of the recess 60 and having a good film quality may be formed. Therefore, the Ti film 61 may be formed while suppressing influence on the silicon layer 64 exposed on the bottom surface of the recess 60.

### <Variations>

Although the above-described embodiment has described the case in which the Ti film 61 is formed as a metal film, the metal film formed by supplying a metal raw material gas based on the time chart illustrated in FIG. 13 is not limited thereto. For example, the embodiment may be applied to forming a tungsten film (W film) by using a tungsten hexafluoride (WF₆) gas or tungsten pentachloride (WCl₅) gas. Halogen (fluorine or chlorine) atoms contained in these tungsten raw material gases (W raw material gases) may also be regarded as atoms that react with moisture in the atmosphere to generate corrosive substances (HF or HCl).

The embodiments disclosed herein should be considered to be illustrative and not restrictive in all respects. The above embodiments may be omitted, substituted, or modified in various ways without departing from the scope or spirit of the appended claims.

### Examples

### (Experiment 1)

The Ti film 61 was formed based on the time chart according to the improved embodiment illustrated in FIG. 5 (corresponding to the second step of the time chart according to the embodiment illustrated in FIG. 13) and the time chart according to the conventional embodiment illustrated in FIG. 2, and selectivity of film formation was confirmed.

### A. Experimental Conditions

(Example 1) For the wafer W on which the recess 60 having an opening diameter of 40 nm and a depth of 120 nm was formed, the Ti film 61 was formed based on the time chart illustrated in FIG. 5. The processing temperature was 400 degrees C. and the processing pressure was 133 Pa (1 Torr). Further, the supply time of the TiCl₄ gas in one cycle was set to 6 seconds and the stop time was set to 24 seconds, and this cycle was repeated 40 times (the cumulative value of the supply time of the TiCl₄ gas: 240 seconds).

(Comparative Example 1) For the wafer W similar to that of Example 1, the Ti film 61 was formed based on the time chart illustrated in FIG. 2. The processing temperature was 400 degrees C. and the processing pressure was 1,200 Pa (9 Torr). Further, the continuous supply time of the TiCl₄ gas was set to 360 seconds.

(Reference Example 1) The Ti film 61 was formed under the same conditions as those of Comparative Example 1, except that the processing temperature was set to 450 degrees C.

### B. Experiment Results

Table 1 shows film thicknesses of the Ti film 61 formed on the sidewall surface and the bottom surface of the recess 60 for Example 1, Comparative Example 1, and Reference Example 1, respectively. In addition, in Table 1, the TiCl₄ gas supply time indicates the cumulative value of the supply time for Example 1 and the continuous supply time for Comparative Example 1 and Reference Example 1.

TABLE 1

| | | | Comparative | Reference | |
|---|---|---|---|---|---|
| | Example 1 | | Example 1 | Example 1 | |
| Processing temperature | 400 °C | | | 450 | °C |
| Processing pressure | 133 | Pa | 1200 Pa | | |
| TiCl₄ gas supply time | 240 | (sec.) | 360 (sec.) | | |
| Film thickness on | 12 | Å | 6 Å | 13 | Å |
| sidewall surface | | | | | |
| Film thickness on | 74 | Å | 44 Å | 58 | Å |
| bottom surface | | | | | |

According to the results illustrated in Table 1, as compared to Reference Example 1, Example 1 has the thicker Ti film 61 formed on the bottom surface of the recess 60, despite having a lower processing temperature and processing pressure and a shorter TiCl₄ gas supply time. On the other hand, the thickness of the Ti film 61 formed on the sidewall surface of the recess 60 is substantially the same in Example 1 and Reference Example 1. Accordingly, it could be confirmed that Example 1 is a method for forming the Ti film 61 with high selectivity with respect to the bottom surface of the recess 60. In contrast, in Comparative Example 1 in which only the processing temperature was lowered as compared with the film formation conditions of the Ti film 61 in Reference Example 1, the film thickness of the Ti film on the bottom surface of the recess 60 became thinner as the processing temperature was lowered.

### (Experiment 2)

The selectivity of film formation with respect to the sidewall surface/the bottom surface of the recess 60 was confirmed by varying the pressure condition during the formation of the Ti film 61.

### A. Experimental Conditions

(Example 2-1) The Ti film 61 was formed with the processing pressure set to 200 Pa (1.5 Torr), while the number of repetitions of 2 seconds of TiCl₄ gas supply and 1 second of stop was varied among 140, 120, and 100 times (the cumulative values of the supply time of the TiCl₄ gas: 280, 240, and 200 seconds).

(Example 2-2) The Ti film 61 was formed under the same conditions as in Example 2-1, except that the processing pressure was set to 133 Pa (1.0 Torr).

(Example 2-3) The Ti film 61 was formed under the same conditions as in Example 2-1, except that the processing pressure was set to 107 Pa (0.8 Torr).

### B. Experiment Results

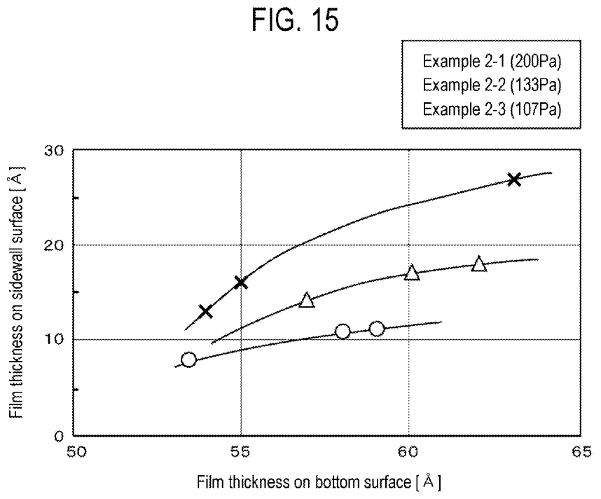

Results of Examples 2-1 to 2-3 are illustrated in FIG. 15. In FIG. 15, the horizontal axis represents the film thickness of the Ti film 61 on the bottom surface side of the recess 60, and the vertical axis represents the film thickness of the Ti film 61 on the sidewall surface side of the recess 60. The results of Example 2-1 (processing pressure: 200 Pa) are illustrated as a plot of ×marks, the results of Example 2-2 (processing pressure: 133 Pa) are illustrated as a plot of white triangle marks, and the results of Example 2-3 (processing pressure: 107 Pa) are illustrated as a plot of white circle marks.

According to these results, it is possible to confirm that, as the processing pressure is lowered, the selectivity of the film thickness of the Ti film 61 varies such that the Ti film 61 on the bottom surface of the recess 60 becomes thicker than that on the sidewall surface of the recess 60.

According to the present disclosure, a metal film may be formed while suppressing influence on a semiconductor layer exposed on a bottom surface of a recess.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a metal film in a recess formed on a surface of a substrate, comprising:
supplying a metal raw material gas containing a metal to the substrate in which a surface of a semiconductor layer containing a dopant is exposed on a bottom surface of the recess;
in parallel with the supplying the metal raw material gas, continuously supplying, to the substrate, a reaction gas for obtaining the metal film by reacting with the metal raw material gas; and
continuously applying radio frequency power to a space through which the metal raw material gas and the reaction gas flow, to plasma-activate the metal raw material gas and the reaction gas,
wherein the supplying the metal raw material gas includes:
continuously supplying the metal raw material gas; and
alternately repeating supply and stop of the metal raw material gas, after performing the continuously supplying the metal raw material gas.

2. The method of claim 1, wherein the metal raw material gas contains atoms that generate a corrosive substance by reacting with moisture in an atmosphere when remaining in the metal film, and during a period in which the supply of the metal raw material gas is stopped in the alternately repeating the supply and the stop of the metal raw material gas, the atoms that generate the corrosive substance is released when the metal film contacts the plasma-activated reaction gas.

3. The method of claim 1, wherein, in the continuously supplying the metal raw material gas, a continuous supply period of the metal raw material gas is within a range of 30 to 120 seconds, and in the alternately repeating the supply and the stop of the metal raw material gas, a cycle is repeated in which a supply time of the metal raw material gas is within a range of 1 to 10 seconds and the stop of the metal raw material gas is performed for a time within a range of 1 to 5 times the supply time of the metal raw material gas.

4. The method of claim 1, wherein the metal film is a titanium film, the metal raw material gas is titanium tetrachloride, and the reaction gas is a hydrogen gas.

5. The method of claim 4, wherein the semiconductor layer is a silicon layer containing boron as the dopant.

6. The method of claim 1, wherein formation of the metal film is performed under a temperature condition within a range of 390 to 410 degrees C.

7. The method of claim 1, wherein formation of the metal film is performed under a pressure condition within a range of 106.7 to 200 Pa.

8. An apparatus for forming a metal film in a recess formed on a surface of a substrate, comprising:
a processing container accommodating the substrate in which a surface of a semiconductor layer containing a dopant is exposed on a bottom surface of the recess;
a raw material gas supply configured to supply a metal raw material gas containing a metal to the processing container;
a reaction gas supply configured to supply, to the processing container, a reaction gas for obtaining the metal film by reacting with the metal raw material gas;
a radio frequency power supply configured to apply radio frequency power to a space through which the metal raw material gas and the reaction gas flow; and
a controller,
wherein the controller is configured to output a control signal for executing:
supplying the metal raw material gas containing the metal to the substrate within the processing container;
in parallel with the supplying the metal raw material gas, continuously supplying, to the substrate, the reaction gas for obtaining the metal film by reacting with the metal raw material gas; and
continuously applying the radio frequency power to plasma-activate the metal raw material gas and the reaction gas, and
wherein the controller is also configured to output a control signal for executing, in the supplying the metal raw material gas:
continuously supplying the metal raw material gas; and
alternately repeating supply and stop of the metal raw material gas, after performing the continuously supplying the metal raw material gas.

9. The apparatus of claim 8, wherein the metal raw material gas contains atoms that generate a corrosive substance by reacting with moisture in an atmosphere when remaining in the metal film, and during a period in which the supply of the metal raw material gas is stopped in the alternately repeating the supply and the stop of the metal raw material gas, the atoms that generate the corrosive substance is released when the metal film contacts the plasma-activated reaction gas.

10. The apparatus of claim 8, wherein, in the continuously supplying the metal raw material gas, a continuous supply period of the metal raw material gas is within a range of 30 to 120 seconds, and in the alternately repeating the supply and the stop of the metal raw material gas, a cycle is repeated in which a supply time of the metal raw material gas is within a range of 1 to 10 seconds and the stop of the metal raw material gas is performed for a time within a range of 1 to 5 times the supply time of the metal raw material gas.

11. The apparatus of claim 8, wherein the metal film is a titanium film, the metal raw material gas is titanium tetrachloride, and the reaction gas is a hydrogen gas.

12. The apparatus of claim 11, wherein the semiconductor layer is a silicon layer containing boron as the dopant.

13. The apparatus of claim 8, further comprising a heater configured to heat the substrate so that a temperature of the substrate is within a range of 390 to 410 degrees C. during a period in which the metal film is formed.

14. The apparatus of claim 8, further comprising a pressure adjuster configured to perform pressure adjustment so that an internal pressure of the processing container is within a range of 106.7 to 200 Pa during a period in which the metal film is formed.
